(19) United States
(12) Patent Application Publication
(10) Pub. No.: US 2024/0120271 A1
(43) Pub. Date: Apr. 11, 2024

(54) SKIP VIA WITH LATERAL LINE CONNECTION

(71) Applicant: INTERNATIONAL BUSINESS MACHINES CORPORATION, Armonk, NY (US)

(72) Inventors: Nicholas Anthony Lanzillo, Wynantskill, NY (US); Koichi Motoyama, Clifton Park, NY (US); Ruilong Xie, Niskayuna, NY (US); Lawrence A. Clevenger, Saratoga Springs, NY (US)

(21) Appl. No.: 17/963,281

(22) Filed: Oct. 11, 2022

(51) Int. Cl. H01L 23/522; H01L 21/306; H01L 21/3205; H01L 23/528

(52) U.S. Cl. CPC H01L 23/5226; H01L 21/306; H01L 21/32051; H01L 23/528

(57) ABSTRACT

A semiconductor structure is presented including a first level of interconnect wiring, a second level of interconnect wiring disposed above the first level of interconnect wiring, a third level of interconnect wiring disposed above the second level of interconnect wiring, and a skip via extending from the third level of interconnect wiring to the first level of interconnect wiring such that a sidewall of the skip via maintains electrical contact with the second level of interconnect wiring. A contact area between the sidewall of the skip via and the second level of interconnect wiring is greater than a contact area between a bottom portion of the skip via and a top portion of the first level of interconnect wiring.

### BACKGROUND

The present invention relates generally to semiconductor devices, and more specifically, to constructing a skip via with a lateral line connection.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a first level of interconnect wiring, a second level of interconnect wiring disposed above the first level of interconnect wiring, a third level of interconnect wiring disposed above the second level of interconnect wiring, and a skip via extending from the third level of interconnect wiring to the first level of interconnect wiring such that a sidewall of the skip via maintains electrical contact with the second level of interconnect wiring.

In accordance with another embodiment, a semiconductor structure is provided. The semiconductor structure includes a bottom level of interconnect wiring, a plurality of middle levels of interconnect wiring disposed above the bottom level of interconnect wiring, a top level of interconnect wiring disposed above the plurality of middle levels of interconnect wiring, and a skip via extending from the top level of interconnect wiring to the bottom level of interconnect wiring such that a sidewall of the skip via maintains electrical contact with all of the plurality of middle levels of interconnect wiring.

In accordance with yet another embodiment, a method for forming a semiconductor structure is provided. The method includes forming a first level of interconnect wiring, forming a second level of interconnect wiring disposed above the first level of interconnect wiring, forming a third level of interconnect wiring disposed above the second level of interconnect wiring, and forming a skip via extending from the third level of interconnect wiring to the first level of interconnect wiring such that a sidewall of the skip via maintains electrical contact with the second level of interconnect wiring.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view comparing skip via configurations of a first conventional semiconductor structure and the novel semiconductor structure, in accordance with an embodiment of the present invention;

FIG. 2 is a cross-sectional view comparing skip via configurations of a second conventional semiconductor structure and the novel semiconductor structure, in accordance with an embodiment of the present invention;

FIG. 3 is a cross-sectional view of a semiconductor structure illustrating first, second, and third levels of interconnect wiring where the third level of interconnect wiring is etched, in accordance with an embodiment of the present invention;

FIG. 4 is a cross-sectional view of the semiconductor structure of FIG. 3 where a wet etch is performed down to the second level of interconnect wiring, in accordance with an embodiment of the present invention;

FIG. 5 is a cross-sectional view of the semiconductor structure of FIG. 4 where a dry etch is performed through the second level of interconnect wiring, in accordance with an embodiment of the present invention:

FIG. 6 is a cross-sectional view of the semiconductor structure of FIG. 5 where a wet etch is performed down to the first level of interconnect wiring, in accordance with an embodiment of the present invention;

FIG. 7 is a cross-sectional view comparing contact areas between the conventional semiconductor structure and the novel semiconductor structure, in accordance with an embodiment of the present invention; and

FIG. 8 is a block/flow diagram of a method for constructing a skip via with a lateral line connection, in accordance with an embodiment of the present invention.

Throughout the drawings, same or similar reference numerals represent the same or similar elements.

### DETAILED DESCRIPTION

Embodiments in accordance with the present invention provide methods and devices for constructing a skip via with a lateral line connection. The skip-level vias of the exemplary embodiments maintain an electrical connection to the middle line level. The exemplary skip via thus electrically connects three different line levels, such as, e.g., M1, M2, and M3. The exemplary skip via also makes contact to a line level (e.g., M2) through the sidewall of the skip via, while simultaneously or concurrently making contact to a line (e.g., M1) below the bottom of the skip via.

The exemplary semiconductor structure further includes first, second, and third levels of interconnect wiring. A direct via connection is present between the first and third levels of interconnect wiring. An electrical connection is also present between the sidewall of the skip via and the second level of interconnect wiring. The contact area between the sidewall of the skip via and the middle wiring level (or second level M2) is larger than the contact area between the bottom of the skip via and the top of the first wiring level (first level M1).

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

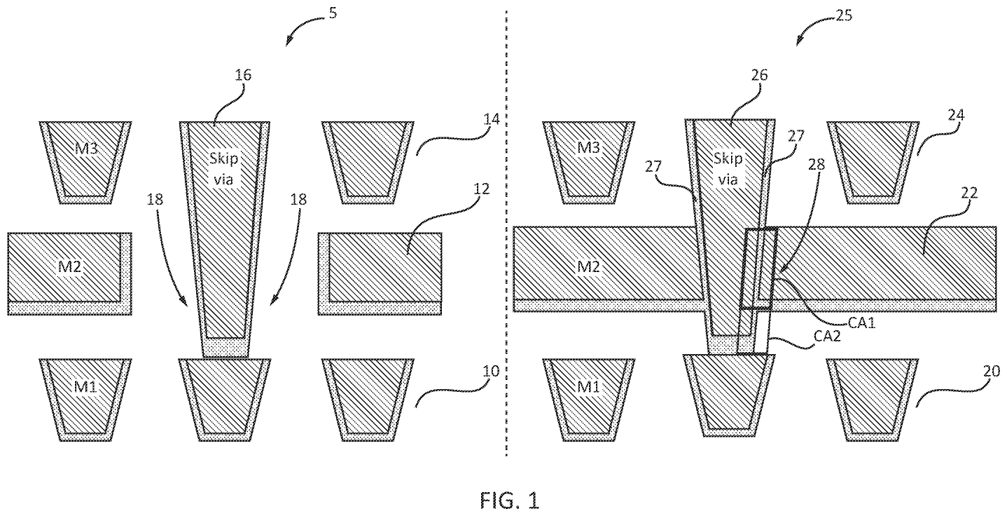

FIG. 1 is a cross-sectional view comparing skip via configurations of a first conventional semiconductor structure and the novel semiconductor structure, in accordance with an embodiment of the present invention.

A first conventional semiconductor structure 5 depicts a first level of interconnect wiring 10, a second level of interconnect wiring 12, and a third level of interconnect wiring 14. The first level of interconnect wiring 10 is designated as M1, the second level of interconnect wiring 12 is designated as M2, and the third level of interconnect wiring 14 is designated as M3. A skip via 16 is depicted that extends from the third level of interconnect wiring 14 to the first level of interconnect wiring 10. The skip via 16 is insulated from the neighboring lines in areas 18. In other words, the skip via 16 is insulated from the second level of interconnect wiring 12. The areas 18 designate the spacing or gap between the skip via 16 and the second level of interconnect wiring 12.

The novel semiconductor structure 25 depicts a first level of interconnect wiring 20, a second level of interconnect wiring 22, and a third level of interconnect wiring 24. The first level of interconnect wiring 20 is designated as M1, the second level of interconnect wiring 22 is designated as M2, and the third level of interconnect wiring 24 is designated as M3. A skip via 26 is depicted that extends from the third level of interconnect wiring 24 to the first level of interconnect wiring 20. The skip via 26 is intentionally shorted to the second level of interconnect wiring 22. In other words, the sidewalls 27 of the skip via 26 directly contact the second level of interconnect wiring 22. The contact area is designated as 28. In fact, there are two contact areas, that is, contact area 1 (CA1) and contact area 2 (CA2). CA1 is the contact area between the second level of interconnect wiring 22 and the sidewall 27 of the skip via 26. CA2 is the contact area between the skip via 26 and the top portion of the first level of interconnect wiring 20. CA1 is larger than CA2. Thus, contact between the second level of interconnect wiring 22 and the sidewall 27 of the skip via 26 is greater than or larger than contact between the skip via 26 and the top portion of the first level of interconnect wiring 20.

Therefore, the skip-via structure includes a first level of interconnect wiring, a second level of interconnect wiring disposed above the first level of interconnect wiring, a third level of interconnect wiring disposed above the second level of interconnect wiring, and a skip via extending from the third level of interconnect wiring to the first level of interconnect wiring such that a sidewall of the skip via maintains electrical contact with the second level of interconnect wiring. The skip via electrically connects the first, second, and third levels of interconnect wiring. The skip via extends entirely through the second level of interconnect wiring. A contact area between the sidewall of the skip via and the second level of interconnect wiring is greater than a contact area between a bottom portion of the skip via and a top portion of the first level of interconnect wiring. The electrical contact between the skip via and the second level of interconnect wiring defines a lateral line connection. A contact area between the sidewall of the skip via and the second level of interconnect wiring defines a substantially vertical contact area.

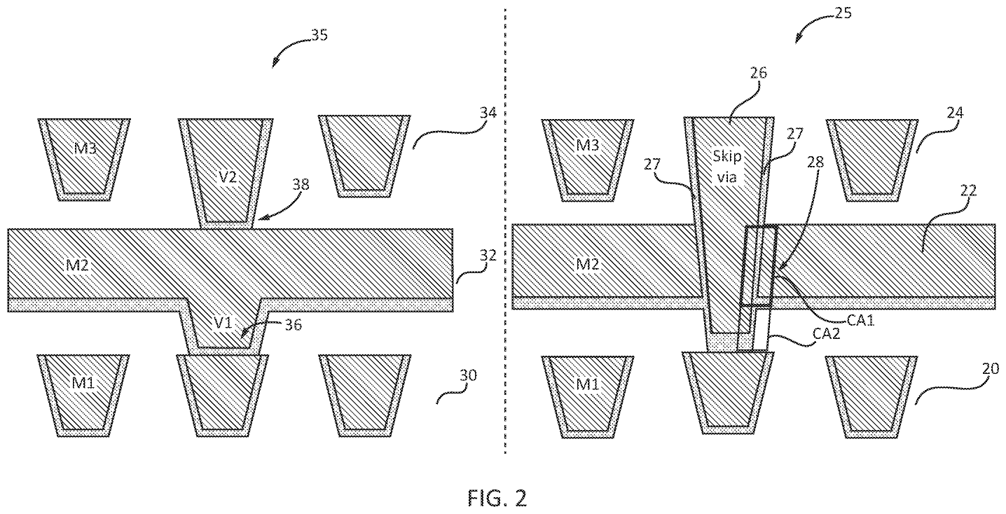

FIG. 2 is a cross-sectional view comparing skip via configurations of a second conventional semiconductor structure and the novel semiconductor structure, in accordance with an embodiment of the present invention.

A second conventional semiconductor structure 35 depicts a first level of interconnect wiring 30, a second level of interconnect wiring 32, and a third level of interconnect wiring 34. The first level of interconnect wiring 30 is designated as M1, the second level of interconnect wiring 32 is designated as M2, and the third level of interconnect wiring 34 is designated as M3. A first via 36 (V1) and a second via 38 (V2) are depicted that collectively extend from the third level of interconnect wiring 34 to the first level of interconnect wiring 30. Therefore, two barriers are present between M3 and M1. The first via 36 and the second via 38 can be referred to as a stacked via configuration. The first via 36 does not extend through the second level of interconnect wiring 32.

Moreover, the sidewall 27 (barrier layer) in FIG. 2 could be composed of multiple materials. While the sidewall 27 is depicted as a single material, in alternative embodiments, the sidewall 27 could be a bilayer or even a trilayer structure. In one example, a representative composition could be a few nanometers of tantalum nitride (TaN) with a few nanometers of cobalt (Co) on top of it.

The novel semiconductor structure 25 depicts a first level of interconnect wiring 20, a second level of interconnect wiring 22, and a third level of interconnect wiring 24. The first level of interconnect wiring 20 is designated as M1, the second level of interconnect wiring 22 is designated as M2, and the third level of interconnect wiring 24 is designated as M3. A skip via 26 is depicted that extends from the third level of interconnect wiring 24 to the first level of interconnect wiring 20. The skip via 26 is intentionally shorted to the second level of interconnect wiring 22. In other words, the sidewalls 27 of the skip via 26 directly contact the second level of interconnect wiring 22. The contact area is designated as 28. In fact, there are two contact areas, that is, contact area 1 (CA1) and contact area 2 (CA2). CA1 is the contact area between the second level of interconnect wiring 22 and the sidewall 27 of the skip via 26. CA2 is the contact area between the skip via 26 and the top portion of the first level of interconnect wiring 20. CA1 is larger than CA2. Thus, contact between the second level of interconnect wiring 22 and the sidewall 27 of the skip via 26 is greater than or larger than contact between the skip via 26 and the top portion of the first level of interconnect wiring 20. Also, the skip via structure has both lateral and bottom contact areas.

Therefore, the skip via 26 of the exemplary embodiments maintains an electrical connection to the middle line level (M2). The exemplary skip via 26 thus electrically connects three different line levels, such as M1, M2, and M3. The exemplary skip via 26 also makes contact to a line level (e.g., M2) through the sidewall 27 of the skip via 26, while simultaneously or concurrently making contact to a line (e.g., M1) below the bottom of the skip via 26. As a result, the skip via 26 makes electrical connection or electrical contact with an intermediate or middle metal level resulting in a via connection between three metal levels, that is, a lower metal, a middle metal, and an upper metal (e.g., metal lines M1, M2, M3). The electrical connection to the middle line level is made through the sidewall of the skip via (as opposed to the bottom of the via).

Non-limiting examples of suitable conductive materials for the first level of interconnect wiring 20, the second level of interconnect wiring 22, and the third level of interconnect wiring 24 include a refractory metal liner such as TaN, an adhesion metal liner, such as Co or Ru, and a conductive metal fill, such as Al, W, Cu, Co, Ru, etc. The conductive material can further include dopants that are incorporated during or after deposition. The conductive metal can be deposited by a suitable deposition process, for example, CVD, PECVD, PVD, plating, thermal or e-beam evaporation, and sputtering.

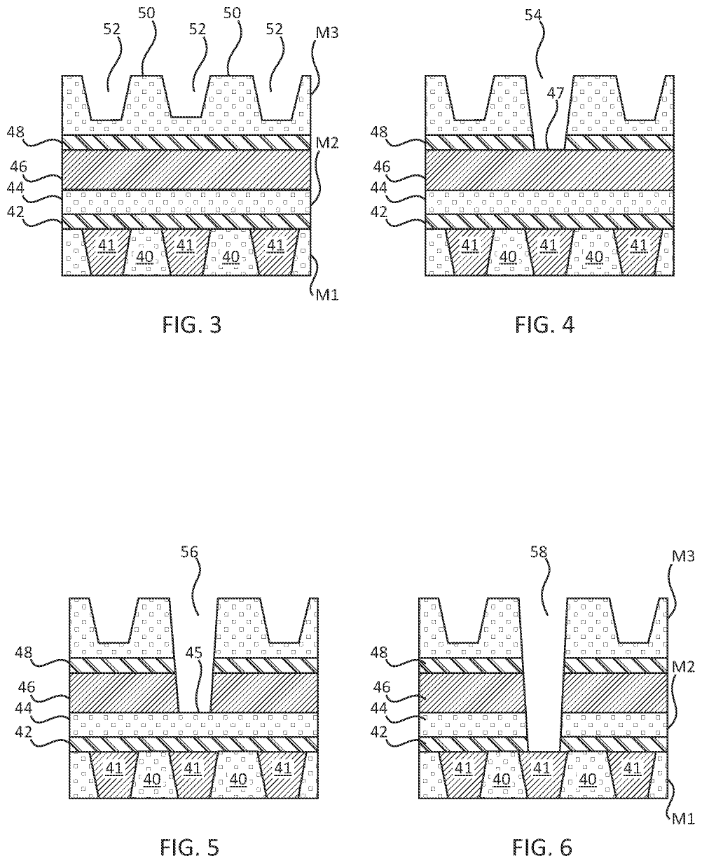

FIG. 3 is a cross-sectional view of a semiconductor structure illustrating first, second, and third levels of interconnect wiring where the third level of interconnect wiring is etched, in accordance with an embodiment of the present invention.

In various example embodiments, a first level of interconnect wiring 40 is separated by insulating portions 41. A capping layer 42 is formed over the first level of interconnect wiring 40 separated by the insulating portions 41. A second level of interconnect wiring 44 is formed over the capping layer 42. An insulating layer 46 is formed over the second level of interconnect wiring 44. A second capping layer 48 is then formed over the insulating layer 46. A third level of interconnect wiring 50 is formed over the second capping layer 48. The third level of interconnect wiring 50 is etched to form openings 52 in the third level of interconnect wiring 50.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

Regarding various dielectrics or dielectric layers discussed herein, the dielectrics can include, but are not limited to, SiN, SiOCN, SiOC, SiC, SiON, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

FIG. 4 is a cross-sectional view of the semiconductor structure of FIG. 3 where a wet etch is performed down to the second level of interconnect wiring, in accordance with an embodiment of the present invention.

In various example embodiments, an opening 54 is created through the second capping layer 48 to the top surface 47 of the insulating layer 46. This is considered a wet etch down to the level of interconnect wiring 44.

FIG. 5 is a cross-sectional view of the semiconductor structure of FIG. 4 where a dry etch is performed through the second level of interconnect wiring, in accordance with an embodiment of the present invention.

In various example embodiments, an opening 56 is created through the insulating layer 46 to a top surface 45 of the second level of interconnect wiring 44. This is considered a dry etch through the second level of interconnect wiring 44.

FIG. 6 is a cross-sectional view of the semiconductor structure of FIG. 5 where a wet etch is performed down to the first level of interconnect wiring, in accordance with an embodiment of the present invention.

In various example embodiments, an opening 58 is created to a top surface of an insulating portion 41. This is considered a wet etch down to the first level of interconnect wiring 40. This step results in the creation of the skip via 26 (FIGS. 1 and 2) which will then be filled with a conductive material (not shown).

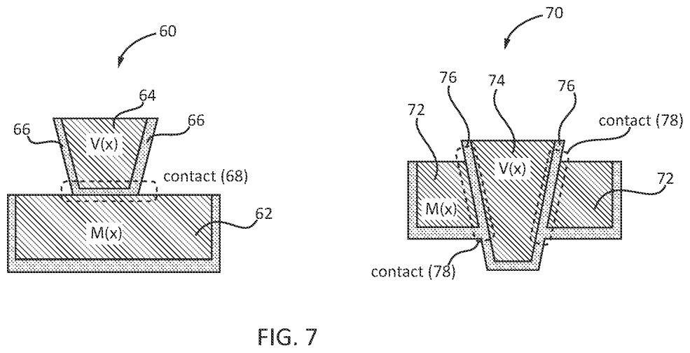

FIG. 7 is a cross-sectional view comparing contact areas between the conventional semiconductor structure and the novel semiconductor structure, in accordance with an embodiment of the present invention.

The conventional structure 60 depicts a first level of interconnect wiring 62 and a via 64 formed over the first level of interconnect wiring 62. The sidewalls 66 of the via 64 contact the first level of interconnect wiring 62 to define contact area 68. The contact area 68 is a horizontal portion between the via 64 and the first level of interconnect wiring 62.

The novel structure 70 depicts a first level of interconnect wiring 72 and a skip via 74 extending through the first level of interconnect wiring 72. The sidewalls 76 of the skip via 74 contact the sidewalls of the first level of interconnect wiring 72 to define contact areas 78. Thus, there are two contacts areas 78 on opposed ends of the skip via 74. The contacts areas 78 of the novel structure 70 are greater than the contact area 68 of the conventional structure 60.

The contacts areas 78 are also substantially vertical (as opposed to horizontal) as they extend along the sidewalls 76 of the skip via 74.

The dimensions in the example below are all approximate dimensions corresponding to an interconnect architecture with 30 nm pitch. In the example, lines may be taller or shorter than assumed, the width could be larger or smaller, and the TaN thickness could be larger or smaller.

The contact area of the conventional structure 60 is given as:

πr²=π(7.5 nm)²=176 nm²

In contrast, the contact area of the novel structure 70 is:

2×height×width=2*15*30=900 nm²

This results in a 5× increase in contact area.

The barrier/liner of the conventional structure 60 is:

2 nm PVD TaN.

The barrier/liner of the novel structure 70 is:

0.6 nm PVD TaN with 30% sidewall coverage.

As a result, there is a 60% thinner barrier at the interface.

The estimated resistance for the conventional structure 60 is ˜30Ω

The estimated resistance for the novel structure 70 is ˜2Ω

This results in a 15× decrease in via resistance.

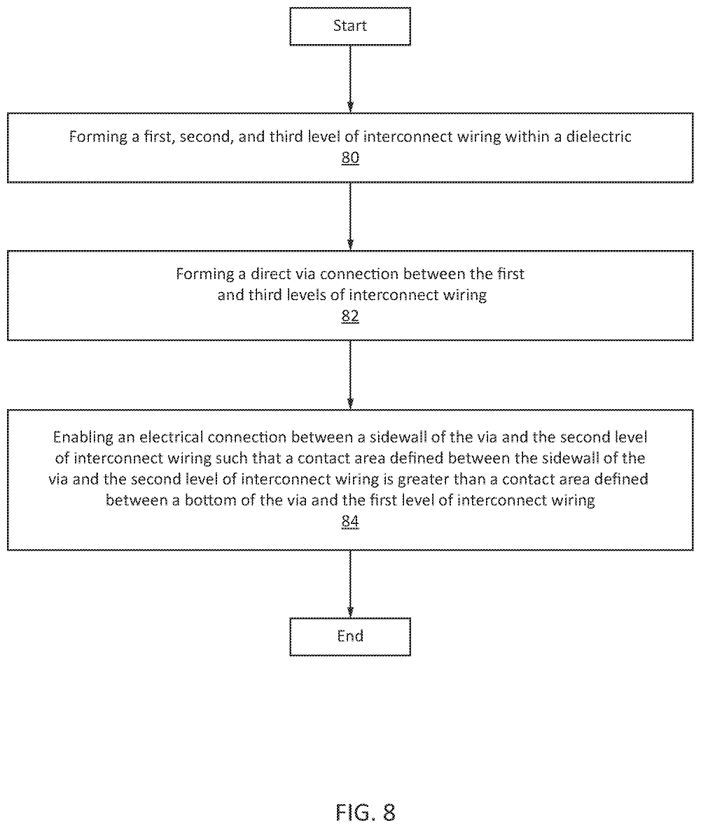

FIG. 8 is a block/flow diagram of a method for constructing a skip via with a lateral line connection, in accordance with an embodiment of the present invention.

At block 80, form a first, second, and third level of interconnect wiring within a dielectric.

At block 82, form a direct via connection between the first and third levels of interconnect wiring.

At block 84, enable an electrical connection between a sidewall of the skip via and the second level of interconnect wiring such that a contact area defined between the sidewall of the skip via and the second level of interconnect wiring is greater than a contact area defined between a bottom of the skip via and the first level of interconnect wiring.

In semiconductor design technology, many metal layers are employed to implement interconnections throughout an integrated circuit. For some integrated circuits, one or more polysilicon (poly) layers, or even active areas, are also used to implement interconnections. Vias are employed to connect from one such metal or polysilicon layer to another metal or polysilicon layer. For example, a via can be used to connect a feature (e.g., a design geometry) on each of two metal layers. The lower one of the two layers is referred to as the landing metal layer and the upper one of the two layers is referred to as the covering layer. A via between a landing metal layer mtₓ and the covering metal layer mtₓ₊₁ is usually referred to as a vₓ via (e.g., using the same subscript designation as the landing metal layer). Embodiments in accordance with the present invention provide methods and devices for incorporating skip vias (or super vias) in an integrated circuit design such that the skip via has a lateral line connection.

Therefore, the skip via of the exemplary embodiments maintains an electrical connection to the middle line level (M2). The exemplary skip via also electrically connects three different line levels, such as M1, M2, and M3. The exemplary skip via further makes contact to a line level (e.g., M2) through the sidewall of the skip via, while simultaneously or concurrently making contact to a line (e.g., M1) below the bottom of the skip via. As a result, the skip via makes electrical connection or electrical contact with an intermediate or middle metal level resulting in a via connection between three metal levels, that is, a lower metal, a middle metal, and an upper metal (e.g., metal lines M1, M2, M3). The electrical connection to the middle line level is made through the sidewall of the skip via (as opposed to the bottom of the via).

In conclusion, the exemplary embodiments of the present invention introduce a first, second, and third level of interconnect wiring. A direct via connection is present between the first and third levels of interconnect wiring. An electrical connection is also present between the sidewall of the skip via and the second level of interconnect wiring. The contact area between the sidewall of the skip via and the middle wiring level is larger than the contact area between the bottom of the skip via and the top of the first wiring level.

In another exemplary embodiment, a first, second, third, and fourth levels of interconnect wiring are provided. A direct via connection is present between the first and fourth levels of interconnect wiring. An electrical connection is present between the sidewall of the skip via and at least one of the second or third levels of interconnect wiring. Therefore, in another exemplary embodiment, the skip-via structure can have a bottom level of interconnect wiring, a plurality of middle levels of interconnect wiring disposed above the bottom level of interconnect wiring, a top level of interconnect wiring disposed above the plurality of middle levels of interconnect wiring, and a skip via extending from the top level of interconnect wiring to the bottom level of interconnect wiring such that a sidewall of the skip via maintains electrical contact with all of the plurality of middle levels of interconnect wiring. The skip via electrically connects the bottom, the top, and all of the plurality of middle levels of interconnect wiring. The skip via extends entirely through all of the plurality of middle levels of interconnect wiring. A contact area between the sidewall of the skip via and a middle level of the plurality of middle levels of interconnect wiring is greater than a contact area between a bottom portion of the skip via and a top portion of the first level of interconnect wiring. The electrical contact between the skip via and each of the plurality of middle levels of interconnect wiring defines a lateral line connection. A contact area between the sidewall of the skip via and a middle level of the plurality of middle levels of interconnect wiring defines a substantially vertical contact area. The vertical contact area results in a skip via contact resistance of ˜2Ω. As a result, the skip-level vias of the exemplary embodiments maintain an electrical connection to the middle line level. The exemplary skip via thus connects all different line levels, e.g., M1, M2, M3, etc.

Regarding FIGS. 1-7, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

Non-limiting examples of suitable conductive materials include doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further comprise dopants that are incorporated during or after deposition. The conductive material can be deposited by a suitable deposition process, for example, CVD, PECVD, PVD, plating, thermal or e-beam evaporation, and sputtering.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for a skip via with a lateral line connection (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a first level of interconnect wiring;
a second level of interconnect wiring disposed above the first level of interconnect wiring;
a third level of interconnect wiring disposed above the second level of interconnect wiring; and
a skip via extending from the third level of interconnect wiring to the first level of interconnect wiring such that a sidewall of the skip via maintains electrical contact with the second level of interconnect wiring.

2. The semiconductor structure of claim 1, wherein the skip via electrically connects the first, second, and third levels of interconnect wiring.

3. The semiconductor structure of claim 1, wherein the skip via extends entirely through the second level of interconnect wiring.

4. The semiconductor structure of claim 1, wherein a contact area between the sidewall of the skip via and the second level of interconnect wiring is greater than a contact area between a bottom portion of the skip via and a top portion of the first level of interconnect wiring.

5. The semiconductor structure of claim 1, wherein the electrical contact between the skip via and the second level of interconnect wiring defines a lateral line connection.

6. The semiconductor structure of claim 1, wherein a contact area between the sidewall of the skip via and the second level of interconnect wiring defines a substantially vertical contact area.

7. The semiconductor structure of claim 6, wherein the vertical contact area results in a skip via contact resistance of ˜2Ω.

8. A semiconductor structure comprising:
a bottom level of interconnect wiring;
a plurality of middle levels of interconnect wiring disposed above the bottom level of interconnect wiring;
a top level of interconnect wiring disposed above the plurality of middle levels of interconnect wiring; and
a skip via extending from the top level of interconnect wiring to the bottom level of interconnect wiring such that a sidewall of the skip via maintains electrical contact with all of the plurality of middle levels of interconnect wiring.

9. The semiconductor structure of claim 8, wherein the skip via electrically connects the bottom, the top, and all of the plurality of middle levels of interconnect wiring.

10. The semiconductor structure of claim 8, wherein the skip via extends entirely through all of the plurality of middle levels of interconnect wiring.

11. The semiconductor structure of claim 8, wherein a contact area between the sidewall of the skip via and a middle level of the plurality of middle levels of interconnect wiring is greater than a contact area between a bottom portion of the skip via and a top portion of the first level of interconnect wiring.

12. The semiconductor structure of claim 8, wherein the electrical contact between the skip via and each of the plurality of middle levels of interconnect wiring defines a lateral line connection.

13. The semiconductor structure of claim 8, wherein a contact area between the sidewall of the skip via and a middle level of the plurality of middle levels of interconnect wiring defines a substantially vertical contact area.

14. The semiconductor structure of claim 13, wherein the vertical contact area results in a skip via contact resistance of ˜2Ω.

15. A method comprising:
forming a first level of interconnect wiring;
forming a second level of interconnect wiring disposed above the first level of interconnect wiring;
forming a third level of interconnect wiring disposed above the second level of interconnect wiring; and
forming a skip via extending from the third level of interconnect wiring to the first level of interconnect wiring such that a sidewall of the skip via maintains electrical contact with the second level of interconnect wiring.

16. The method of claim 15, wherein the skip via electrically connects the first, second, and third levels of interconnect wiring.

17. The method of claim 15, wherein the skip via extends entirely through the second level of interconnect wiring.

18. The method of claim 15, wherein a contact area between the sidewall of the skip via and the second level of interconnect wiring is greater than a contact area between a bottom portion of the skip via and a top portion of the first level of interconnect wiring.

19. The method of claim 15, wherein the electrical contact between the skip via and the second level of interconnect wiring defines a lateral line connection.

20. The method of claim 15, wherein a contact area between the sidewall of the skip via and the second level of interconnect wiring defines a substantially vertical contact area.
